(19) United States
(12) Patent Application Publication
(10) Pub. No.: US 2025/0385172 A1
(43) Pub. Date: Dec. 18, 2025

(54) DISPLAY DEVICE AND METHOD OF FABRICATING THE SAME

(71) Applicant: Samsung Display Co., LTD., Yongin-si (KR)

(72) Inventors: Dae Hyuk IM, Yongin-si (KR); Si Joon SONG, Yongin-si (KR)

(21) Appl. No.: 19/049,742

(22) Filed: Feb. 10, 2025

(30) Foreign Application Priority Data
Jun. 17, 2024 (KR) 10-2024-0078079

(51) Int. Cl. H01L 23/498; H10K 59/12; H10K 59/131; H10K 59/95

(52) U.S. Cl. CPC H01L 23/49838; H10K 59/1201; H10K 59/131; H10K 59/95

(57) ABSTRACT

A display device includes: a display panel; a first circuit board comprising a first terminal connected to a pad of the display panel; a second circuit board comprising a third terminal connected to a second terminal of the first circuit board; and a driver circuit on the first circuit board, wherein a first terminal area of the first circuit board on which the first terminal is located and a second terminal area of the first circuit board on which the second terminal is located have different sizes.

### CROSS-REFERENCE TO RELATED APPLICATION

The present application claims priority to and the benefit of Korean Patent Application No. 10-2024-0078079, filed on Jun. 17, 2024, in the Korean Intellectual Property Office, the entire disclosure of which is incorporated herein by reference.

### BACKGROUND

### 1. Field

Aspects of some embodiments of the present disclosure relate to a display device, an electronic device including the same, and a method of fabricating the same.

### 2. Description of the Related Art

Organic light emitting diode displays have self-luminous properties and, unlike liquid crystal displays, generally do not require a separate light source and thus can be reduced in thickness and weight. In addition, organic light emitting diode displays are attracting attention as next-generation displays for televisions, monitors, and portable electronic devices due to their high-quality characteristics such as relatively low power consumption, relatively high luminance, and relatively high response speed.

The above information disclosed in this Background section is only for enhancement of understanding of the background and therefore the information discussed in this Background section does not necessarily constitute prior art.

### SUMMARY

Aspects of some embodiments of the present disclosure relate to a display device, an electronic device including the same, and a method of fabricating the same. For example, aspects of some embodiments relate to a display device, and an electronic device including the same, that may be capable of satisfying a tolerance while preventing or reducing misalignment between a circuit board and a display panel and a method of fabricating the display device.

Aspects of some embodiments of the present disclosure include a display device that may be capable of satisfying a tolerance while preventing or reducing misalignment between a circuit board and a display panel and a method of fabricating the display device.

However, aspects of embodiments according to the present disclosure are not restricted to those set forth herein. The above and other aspects of embodiments according to the present disclosure will become more apparent to one of ordinary skill in the art to which the present disclosure pertains by referencing the detailed description of the present disclosure given below.

According to some embodiments of the present disclosure, a display device includes: a display panel; a first circuit board including a first terminal connected to a pad of the display panel; a second circuit board including a third terminal connected to a second terminal of the first circuit board; and a driver circuit on the first circuit board, wherein a first terminal area of the first circuit board on which the first terminal is located and a second terminal area of the first circuit board on which the second terminal is located have different sizes.

According to some embodiments of the present disclosure, in a method of fabricating a display device, the method includes: preparing a base film which includes a plurality of first circuit boards; calculating a first distance between a first outermost terminal and a second outermost terminal of any one first circuit board of the base film; calculating a second distance between a first outermost pad and a second outermost pad of a display panel; calculating a correction movement distance of the any one first circuit board based on the first distance and the second distance; determining a cutting position of the base film based on the correction movement distance of the any one first circuit board; forming a first circuit board by cutting the base film along the cutting position; placing the first circuit board on the display panel; and performing preliminary alignment between the first circuit board and the display panel based on the correction movement distance.

The characteristics of embodiments according to the present disclosure are not limited to the above-described characteristics and other characteristics which are not described herein will become apparent to those skilled in the art from the following description.

### BRIEF DESCRIPTION OF THE DRAWINGS

These and/or other aspects of some embodiments of the present disclosure will become more apparent and more readily appreciated from the following description of the embodiments, taken in conjunction with the accompanying drawings in which:

FIG. 1 is a plan view of a display device according to some embodiments;

FIG. 2 is an enlarged view of a first circuit board of FIG. 1;

FIGS. 3 through 5 are diagrams for explaining a method of solving an alignment error between first terminals of the first circuit board and pads of a display panel;

FIGS. 6 and 7 are cross-sectional views of the display device according to some embodiments;

FIG. 8 is a flowchart illustrating a method of fabricating a display device according to some embodiments;

FIG. 9 is a plan view of a base film according to some embodiments;

FIG. 10 is a plan view of a first circuit board separated from the base film of FIG. 9; and

FIG. 11 is a cross-sectional view of a display device according to some embodiments in which the first circuit board of FIG. 10 is attached.

FIG. 12 is a block diagram of an electronic device according to one embodiment.

FIGS. 13, 14 and 15 are schematic diagrams of electronic devices according to various embodiments.

### DETAILED DESCRIPTION

Aspects of some embodiments of the present disclosure will now be described more fully hereinafter with reference to the accompanying drawings, in which aspects of some embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

Hereinafter, aspects of some embodiments will be described in more detail with reference to the accompanying drawings.

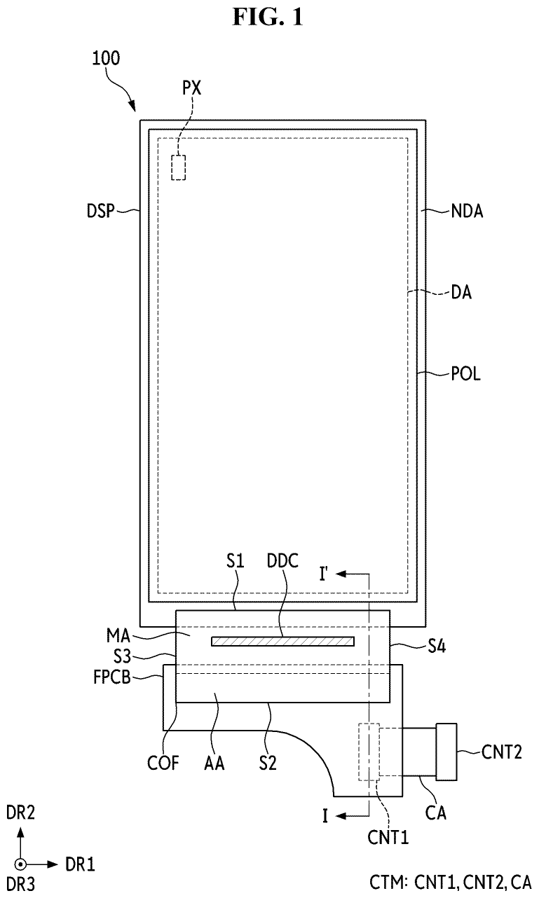

FIG. 1 is a plan view of a display device 100 according to some embodiments.

Referring to FIG. 1, the display device 100 is a device for displaying moving images (e.g., video images) or still images (e.g., static images). The display device 100 may be used as a display screen in electronic devices such as portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards, and Internet of things (IoT) devices. These are presented only as examples, and the display device 100 can also be employed in other electronic devices.

The display device 100 may be a light emitting display device such as an organic light emitting display device including an organic light emitting diode, a quantum dot light emitting display device including a quantum dot light emitting layer, an inorganic light emitting display device including an inorganic semiconductor, or an ultrasmall light emitting display device including an ultrasmall light emitting diode such as a micro- or nano-light emitting diode. However, the present disclosure is not limited thereto. For example, the display device 100 may also be a type of display device other than a light emitting display device. Embodiments in which the display device 100 is a light emitting display device (e.g., an organic light emitting display device) will be disclosed below.

The display device 100 may include a display panel DSP, a first circuit board COF, a second circuit board FPCB, a driver circuit DDC (hereinafter, referred to as a data driver circuit DDC), and a polarizer POL.

The display panel DSP may be provided as a rigid panel that is no deformed (or substantially not deformed) or may be provided as a flexible panel that can be deformed, for example, can be folded, bent, or rolled in at least a portion. The display panel DSP may be provided in an unbent state to the display device 100 or may be provided in a bent state in some sections to the display device 100.

The display panel DSP may include a display area DA and a non-display area NDA.

A plurality of pixels PX may be located in the display area DA. Although FIG. 1 illustrates a single pixel PX, as a person having ordinary skill in the art would appreciate, the display device 100 may include any suitable number of pixels PX according to the design and size of the display device 100. The pixels PX may display images. In addition, a plurality of gate lines and a plurality of emission lines connected to the pixels PX may be located in the display area DA. The display area DA may have various shapes according to embodiments. For example, the display area DA may have a quadrangular shape, a polygonal shape other than the quadrangular shape, a circular shape, an oval shape, an irregular shape, or other shapes. According to some embodiments, the display area DA may have a shape that matches the shape of the display panel DSP.

The non-display area NDA may be arranged around (e.g., in a periphery or outside a footprint of) the display area DA. According to some embodiments, the non-display area NDA may surround (e.g., entirely surround) the display area DA. A gate driver and an emission driver for driving the pixels PX may be located in the non-display area NDA of the display panel DSP. The gate driver may be connected to the gate lines, and the emission driver may be connected to the emission lines. Gate signals from the gate driver may be supplied to the pixels PX through the gate lines, and emission signals from the emission driver may be supplied to the pixels PX through the emission lines.

The first circuit board COF may be connected to the display panel DSP and the second circuit board FPCB. For example, one side of the first circuit board COF may be electrically connected to the non-display area NDA of the display panel DSP, and the other side of the first circuit board COF may be electrically connected to the second circuit board FPCB. The first circuit board COF may be, but is not limited to, a flexible printed circuit board, a printed circuit board, or a flexible film such as a chip on film. The data driver circuit DDC may be located on the first circuit board COF.

The data driver circuit DDC may be connected to the non-display area NDA of the display panel DSP through the first circuit board COF. The data driver circuit DDC may include, for example, an integrated circuit.

A timing controller, a power supply unit, and a connector module CTM may be located on the second circuit board FPCB. The second circuit board FPCB may be, but is not limited to, a flexible printed circuit board, a printed circuit board, or a flexible film such as a chip on film.

The power supply unit may supply power voltages to the pixels PX, the gate driver, the emission driver, and the data driver circuit DDC. The timing controller may control the operations of the gate driver, the emission driver, and the data driver circuit DDC.

Through the first circuit board COF, a gate timing control signal, an emission timing control signal, a gate clock signal, an emission clock signal, a gate start signal, an emission start signal, a high-potential voltage, and a low-potential voltage from the timing controller of the second circuit board FPCB may be supplied to the gate driver and the emission driver. For example, the gate timing control signal, the gate clock signal, the gate start signal, the high-potential voltage, and the low-potential voltage may be supplied to the gate driver, and the emission timing control signal, the emission clock signal, the emission start signal, the high-potential voltage, and the low-potential voltage may be supplied to the emission driver. In addition, power signals from the power supply unit may be supplied to the gate driver, the emission driver, and the pixels PX through the first circuit board COF. The power signals may include, for example, a driving voltage, a common voltage, an initialization voltage, and a bias voltage.

The connector module CTM may be connected to an external system. The connector module CTM may include a first connector CNT1, a second connector CNT2, and a cable CA. The first connector CNT1 may be connected to the second circuit board FPCB, and the second connector CNT2 may be connected to the external system. The cable CA may connect the first connector CNT1 and the second connector CNT2 to each other.

The polarizer POL may be located on the display panel DSP. The polarizer POL may be a structure for preventing or reducing visibility deterioration due to reflection of external light. The polarizer POL may include a linear polarizer and a phase retardation film. For example, the phase retardation film may be a quarter-wave plate (λ/4 plate), but embodiments according to the present specification are not limited thereto.

According to some embodiments, the first circuit board COF may include a first side S1, a second side S2, a third side S3, and a fourth side S4.

The first side S1 of the first circuit board COF may extend, for example, parallel to a first direction DR1. The first side S1 of the first circuit board COF may overlap the display panel DSP. For example, the entire first side S1 of the first circuit board COF may overlap the non-display area NDA (e.g., a pad area of the non-display area NDA) of the display panel DSP.

The second side S2 of the first circuit board COF may extend, for example, parallel to the first direction DR1. The second side S2 of the first circuit board COF may face the first side S1 of the first circuit board COF. The second side S2 of the first circuit board COF and the first side S1 of the first circuit board COF may be parallel to each other. The second side S2 of the first circuit board COF may overlap the second circuit board FPCB. For example, the entire second side S2 of the first circuit board COF may overlap a terminal area of the second circuit board FPCB.

The third side S3 of the first circuit board COF may extend, for example, parallel to a second direction DR2. The third side S3 of the first circuit board COF may be located between one side of the first side S1 and one side of the second side S2. One side of the third side S3 may be connected to the one side of the first side S1, and the other side of the third side S3 may be connected to the one side of the second side S2. The third side S3 of the first circuit board COF may overlap the display panel DSP and the second circuit board FPCB. For example, a part of the third side S3 of the first circuit board COF may overlap the non-display area NDA of the display panel DSP, and another part of the third side S3 may overlap the terminal area of the second circuit board FPCB.

The fourth side S4 of the first circuit board COF may extend, for example, parallel to the second direction DR2. The fourth side S4 of the first circuit board COF may face the third side S3 of the first circuit board COF. The fourth side S4 of the first circuit board COF and the third side S3 of the first circuit board COF may be parallel to each other. The fourth side S4 of the first circuit board COF may be located between the other side of the first side S1 and the other side of the second side S2. One side of the fourth side S4 may be connected to the other side of the first side S1, and the other side of the fourth side S4 may be connected to the other side of the second side S2. The fourth side S4 of the first circuit board COF may overlap the display panel DSP and the second circuit board FPCB. For example, a part of the fourth side S4 of the first circuit board COF may overlap the non-display area NDA of the display panel DSP, and another part of the fourth side S4 may overlap the terminal area of the second circuit board FPCB.

The first circuit board COF may include a main area MA and an auxiliary area AA. For example, an area between the first side S1 of the first circuit board COF and the auxiliary area AA may be defined as the main area MA of the first circuit board COF, and an area between the main area MA and the second side S2 of the first circuit board COF may be defined as the auxiliary area AA of the first circuit board COF.

The data driver circuit DDC may be located in the main area MA of the first circuit board COF, and a plurality of terminals (e.g., first terminals TM1) may be located in the auxiliary area AA of the first circuit board COF.

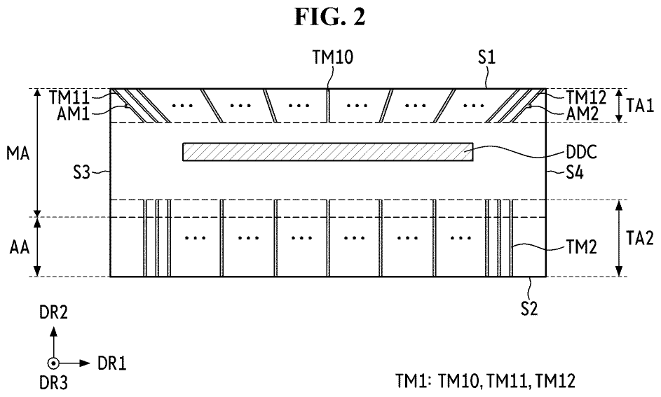

FIG. 2 is an enlarged view of the first circuit board COF of FIG. 1.

The first circuit board COF may include a plurality of first terminals TM1 and a plurality of second terminals TM2.

The first terminals TM1 of the first circuit board COF may be located on one side of the first circuit board COF. For example, the first terminals TM1 may be located in a first terminal area TA1 between the first side S1 of the first circuit board COF and the data driver circuit DDC.

At least one of the first terminals TM1 may be inclined obliquely. For example, at least one of the first terminals TM1 may be inclined at an angle (e.g., a set or predetermined angle) to one end of the first circuit board COF. For example, a first terminal TM1 (hereinafter, referred to as a center terminal TM10) located in the middle among the first terminals TM1 may extend in a direction (e.g., the second direction DR2) parallel to the fourth side S4 (or the second side S2) of the first circuit board COF. First terminals TM1 other than the center terminal TM10 may form a larger angle with the center terminal TM10 as they are located further away from the center terminal TM10. In a specific example, first terminals TM1 located between the center terminal TM10 and the third side S3 of the first circuit board COF may be more rotated along a counterclockwise direction as they are located further away from the center terminal TM10, and first terminals TM1 located between the center terminal TM10 and the fourth side S4 of the first circuit board COF may be more rotated along a clockwise direction as they are located further away from the center terminal TM10. The center terminal TM10 may be, for example, a first terminal TM1 located at a center of the first circuit board COF or a first terminal TM1 located at a center of the first terminal area TA1 of the first circuit board COF.

The second terminals TM2 of the first circuit board COF may be located on the other side of the first circuit board COF. For example, the second terminals TM2 may be located in a second terminal area TA2 between the data driver circuit DDC and the second side S2 of the first circuit board COF. The second terminals TM2 may extend in a direction parallel to a center terminal. For example, the second terminals TM2 may be parallel to the fourth side S4 (or the third side S3). The second terminal area TA2 may include, for example, the auxiliary area AA. In other words, a part of the second terminal area TA2 may be the auxiliary area AA.

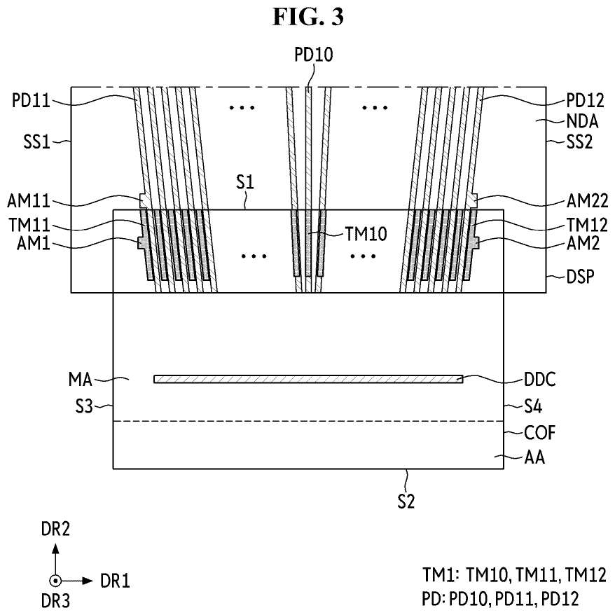

The first terminals TM1 of the first circuit board COF may be connected to pads PD (see FIG. 3) located in the non-display area NDA of the display panel DSP. The first terminals TM1 and the pads PD may be electrically connected directly or through a connecting member such as a conductive ball. Here, the connecting member may include a conductive adhesive member such as an anisotropic conductive film. At least one of the pads PD of the display panel DSP may be inclined obliquely, like the first terminals TM1 of the first circuit board COF.

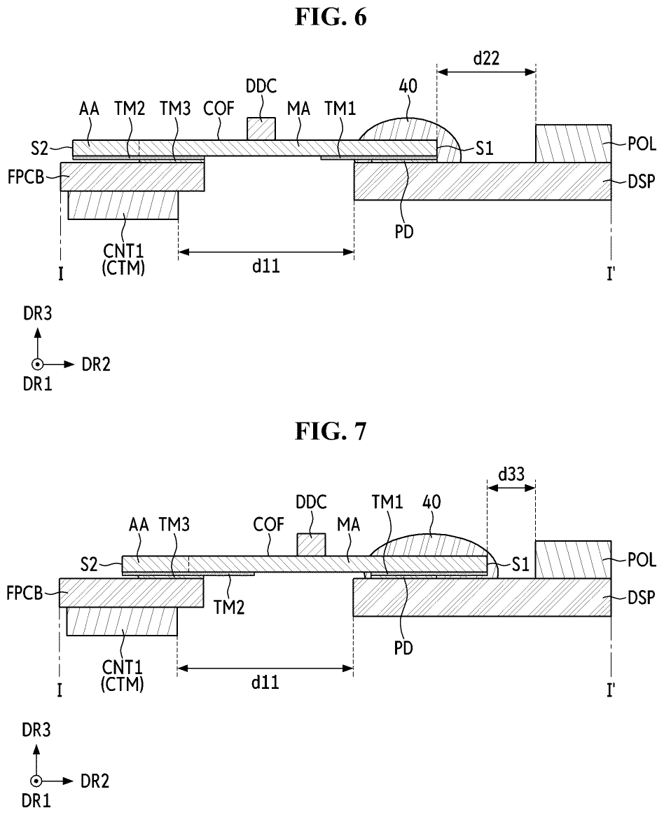

The second terminals TM2 of the first circuit board COF may be connected to terminals TM3 (see FIG. 6; hereinafter, referred to as third terminals TM3) of the second circuit board FPCB. The second terminals TM2 and the third terminals TM3 may be electrically connected directly or through a connecting member such as a conductive ball. Here, the connecting member may include a conductive adhesive member such as an anisotropic conductive film.

According to some embodiments, the first terminal area TA1 and the second terminal area TA2 may have different areas. For example, the second terminal area TA2 may have a larger area than the first terminal area TA1. In a specific example, a size of the second terminal area TA2 in the direction (e.g., the second direction DR2) in which the third side S3 extends may be larger than a size of the first terminal area TA1 in the direction (e.g., the second direction DR2) in which the third side S3 extends. At this time, a size of the second terminal area TA2 in the direction (e.g., the first direction DR1) in which the second side S2 extends may be equal to a size of the first terminal area TA1 in the direction (e.g., the first direction DR1) in which the second side S2 extends.

FIGS. 3 through 5 are diagrams for explaining a method of solving an alignment error between the first terminals TM1 of the first circuit board COF and the pads PD of the display panel DSP.

As illustrated in FIG. 3, at least one of the first terminals TM1 may be inclined obliquely. For example, the first terminals TM1 located between the center terminal TM10 of the first circuit board COF described above and the third side S3 of the first circuit board COF may be more rotated along the counterclockwise direction as they are located further away from the center terminal TM10, and the first terminals TM1 located between the center terminal TM10 of the first circuit board COF and the fourth side S4 may be more rotated along the clockwise direction as they are located further away from the center terminal TM10.

A first terminal TM1 located closest to the third side S3 of the first circuit board COF among the first terminals TM1 may be defined as a first outermost terminal TM11, and a first terminal TM1 located closest to the fourth side S4 of the first circuit board COF among the first terminals TM1 may be defined as a second outermost terminal TM12. In this case, a first alignment mark AM1 (hereinafter, referred to as a first board alignment mark AM1) of the first circuit board COF may be located on an outer surface of the first outermost terminal TM11, and a second alignment mark AM2 (hereinafter, referred to as a second board alignment mark AM2) of the first circuit board COF may be located on an outer surface of the second outermost terminal TM12. Here, the first board alignment mark AM1 and the first outermost terminal TM11 may be integrally formed with each other, and the second board alignment mark AM2 and the second outermost terminal TM12 may be integrally formed with each other.

At least one of the pads PD may be inclined obliquely. Here, a pad PD parallel to a first side SS1 of the display panel DSP among the pads PD is defined as a center pad PD10. The center pad PD10 may be a pad located in the middle among the pads PD or a pad located at a center of the pad area of the display panel DSP. The center pad PD10 and the center terminal TM10 may be parallel to each other. Pads PD located between the center pad PD10 and the first side SS1 of the display panel DSP may be more rotated along the counterclockwise direction as they are located further away from the center pad PD10, and pads PD located between the center pad PD10 and a second side SS2 of the display panel DSP among the pads PD may be more rotated along the clockwise direction as they are located further away from the center pad PD10.

A pad PD located closest to the first side SS1 of the display panel DSP among the pads PD may be defined as a first outermost pad PD11, and a pad PD located closest to the second side SS2 of the display panel DSP among the pads PD may be defined as a second outermost pad PD12. In this case, a first alignment mark AM11 (hereinafter, referred to as a first panel alignment mark AM11) of the display panel DSP may be located on an outer surface of the first outermost pad PD11, and a second alignment mark AM22 (hereinafter, referred to as a second panel alignment mark AM22) of the display panel DSP may be located on an outer surface of the second outermost pad PD12. Here, the first panel alignment mark AM11 and the first outermost pad PD11 may be integrally formed with each other, and the second panel alignment mark AM22 and the second outermost pad PD12 may be integrally formed with each other.

As illustrated in FIG. 3, when the first terminals TM1 and the pads PD are not aligned (e.g., when the first terminals TM1 and the pads PD located on an outer side are not aligned), a distance d1 (hereinafter, referred to as a first distance d1) between the first outermost terminal TM11 and the second outermost terminal TM12 may be different from a distance d2 (hereinafter, referred to as a second distance d2) between the first outermost pad PD11 and the second outermost pad PD12. Specifically, the first distance d1 between the first outermost terminal TM11 and the second outermost terminal TM12 located between the first board alignment mark AM1 and the second board alignment mark AM2 may be different from the second distance d2 between the first outermost pad PD11 and the second outermost pad PD12 located between the first panel alignment mark AM11 and the second panel alignment mark AM22.

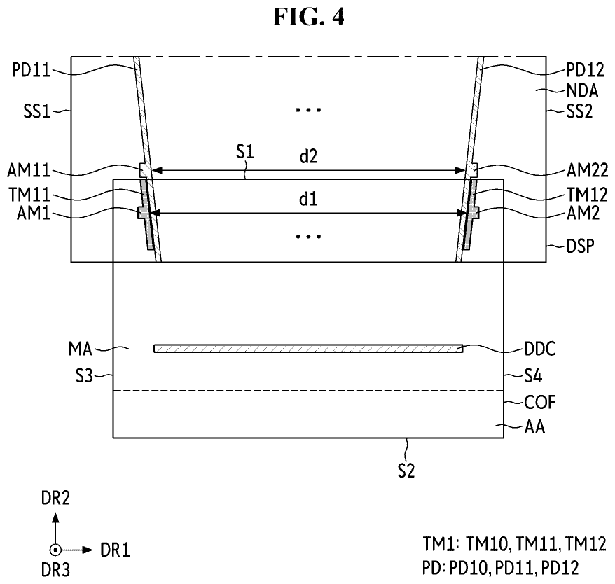

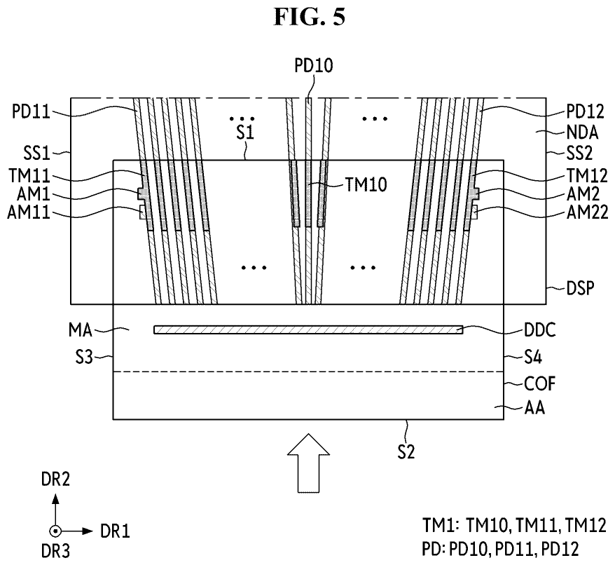

For example, as illustrated in FIG. 4, the first distance d1 may be greater than the second distance d2. When the first terminals TM1 and the pads PD are misaligned due to this distance difference, the first circuit board COF may be moved a distance (e.g., a set or predetermined distance) toward the display panel DSP along the second direction DR2, as illustrated in FIG. 5. Then, the first terminals TM1 of the first circuit board COF and the pads PD of the display panel DSP may be arranged to overlap each other, respectively. Therefore, the first terminals TM1 and the pads PD can be properly aligned. In this way, because the first terminals TM1 of the first circuit board COF and the pads PD of the display panel DSP are arranged along a diagonal direction, even if the first terminals TM1 and the pads PD are misaligned in the first direction DR1, the misalignment problem can be solved or reduce by moving the first circuit board COF in the second direction DR2.

In FIG. 4, for a clear comparison of the first distance d1 and the second distance d2, first terminals TM1 between the first outermost terminal TM11 and the second outermost terminal TM12 and pads PD between the first outermost pad PD11 and the second outermost pad PD12 are all omitted. The first terminals TM1 and the pads PD omitted from FIG. 4 can be found in the first terminals TM1 and the pads PD of FIG. 3.

According to some embodiments, as illustrated in FIG. 5, the first circuit board COF may overlap the display panel DSP more than the second circuit board FPCB.

While the movement of the first circuit board COF in the second direction DR2 solves or reduces the misalignment problem in the first direction DR1 as described above, it may cause a problem of changing a distance between the connector module CTM on the second circuit board FPCB connected to the first circuit board COF and the display panel DSP.

According to some embodiments, because the first circuit board COF includes the auxiliary area AA, the distance between the connector module CTM on the second circuit board FPCB and the display panel DSP can be maintained constant despite the movement of the first circuit board COF. This will be described in detail as follows with reference to FIGS. 6 and 7.

FIGS. 6 and 7 are cross-sectional views of the display device 100 according to some embodiments. For example, FIG. 6 may be a cross-sectional view of the display device 100 of FIG. 1 including the first circuit board COF arranged as illustrated in FIG. 4, taken along the line I-I′. FIG. 7 may be a cross-sectional view of the display device 100 of FIG. 1 including the first circuit board COF arranged as illustrated in FIG. 5, taken along the line I-I′.

First, as illustrated in FIGS. 6 and 7, a protective layer 40 and the polarizer POL may be located on the display panel DSP. For example, the protective layer 40 and the polarizer POL may be located on the display panel DSP in a third direction DR3.

As illustrated in FIG. 6, when the first circuit board COF is attached to the display panel DSP such that a distance d11 between the connector module CTM on the second circuit board FPCB and the display panel DSP satisfies a tolerance range, misalignment may occur between the first terminals TM1 of the first circuit board COF and the pads PD of the display panel DSP.

In order to solve or reduce the misalignment problem between the first terminals TM1 and the pads PD, the first circuit board COF may be moved toward the display panel DSP (e.g., in the second direction DR2). In this case, the distance d11 between the connector module CTM on the second circuit board FPCB and the display panel DSP may be reduced. For example, the distance d11 between the first connector CNT1 of the connector module CTM and the display panel DSP may be reduced. In this case, the distance between the connector module CTM and the display panel DSP may not satisfy the tolerance, causing, for example, interference between the first connector CNT1 and the display panel DSP.

However, according to some embodiments, as illustrated in FIG. 7, a rear part of the first circuit board COF has a size increased by the auxiliary area AA. Therefore, even if the first circuit board COF is moved along the second direction DR2 to solve or reduce the misalignment problem, the distance between the connector module CTM and the display panel DSP can be maintained at a distance that satisfies the tolerance. In other words, because the second terminal area TA2 of the first circuit board COF has a greater length than the first terminal area TA1 in the second direction DR2, even if the first circuit board COF is moved along the second direction DR2 to solve or reduce the misalignment problem, the distance between the connector module CTM and the display panel DSP can be maintained at a distance that satisfies the tolerance. For example, after the first circuit board COF is moved a distance (e.g., a set or predetermined distance) along the second direction DR2 to solve or reduce misalignment, the second circuit board FPCB may be attached to the auxiliary area AA located at a rear end of the main area MA of the first circuit board COF. Therefore, the distance between the connector module CTM on the second circuit board FPCB and the display panel DSP can satisfy the tolerance. For example, as illustrated in FIG. 7, a third terminal TM3 of the second circuit board FPCB may be connected to a second terminal TM2 of the first circuit board COF while overlapping the main area MA and the auxiliary area AA of the first circuit board COF. According to some embodiments, the third terminal TM3 of the second circuit board FPCB may overlap the auxiliary area AA more than the main area MA. According to some embodiments, the third terminal TM3 of the second circuit board FPCB may be connected to the second terminal TM2 of the first circuit board COF while overlapping the auxiliary area AA of the first circuit board COF.

A distance d11 between the connector module CTM and the display panel DSP in FIG. 7 may be equal to the distance d11 between the connector module CTM and the display panel DSP in FIG. 6 described above. In other words, the distance d11 between the connector module CTM and the display panel DSP in FIG. 7 may satisfy the tolerance.

As illustrated in FIG. 7, as the first circuit board COF moves further toward the display panel DSP, a distance d33 between the first circuit board COF and the polarizer POL on the display panel DSP may be reduced. Therefore, the distance d33 between the first circuit board COF and the polarizer POL may not satisfy a tolerance. If the distance d33 between the first circuit board COF and the polarizer POL does not satisfy the tolerance, it may be difficult to apply resin that is used as the protective layer 40.

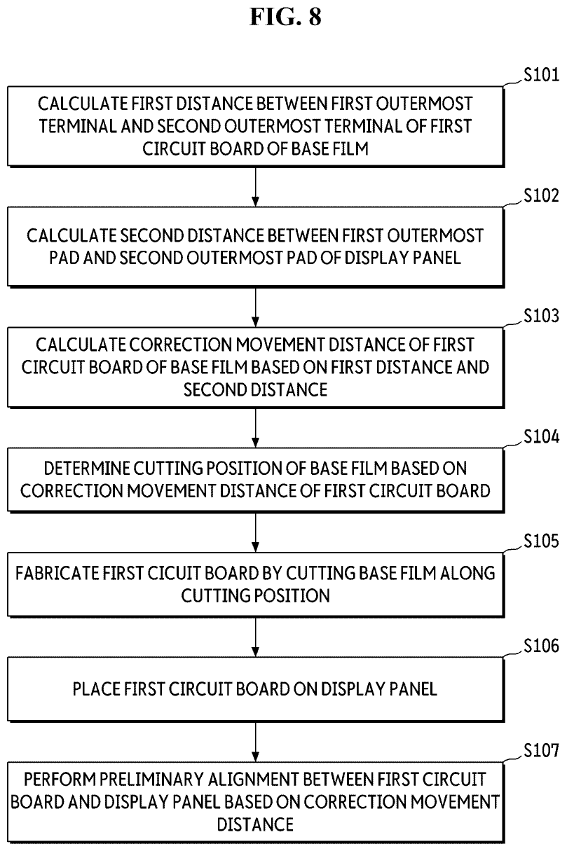

In order to solve or reduce this problem, a method of fabricating a display device according to some embodiments will be described in more detail with reference to FIGS. 8 through 11.

FIG. 8 is a flowchart illustrating aspects of a method of fabricating a display device according to some embodiments. Although FIG. 8 illustrates various operations in a method of fabricating a display device, embodiments according to the present disclosure are not limited thereto, and according to various embodiments the method may include additional operations or fewer operations, or the order of operations may vary, unless otherwise stated or implied, without departing from the spirit and scope of embodiments according to the present disclosure.

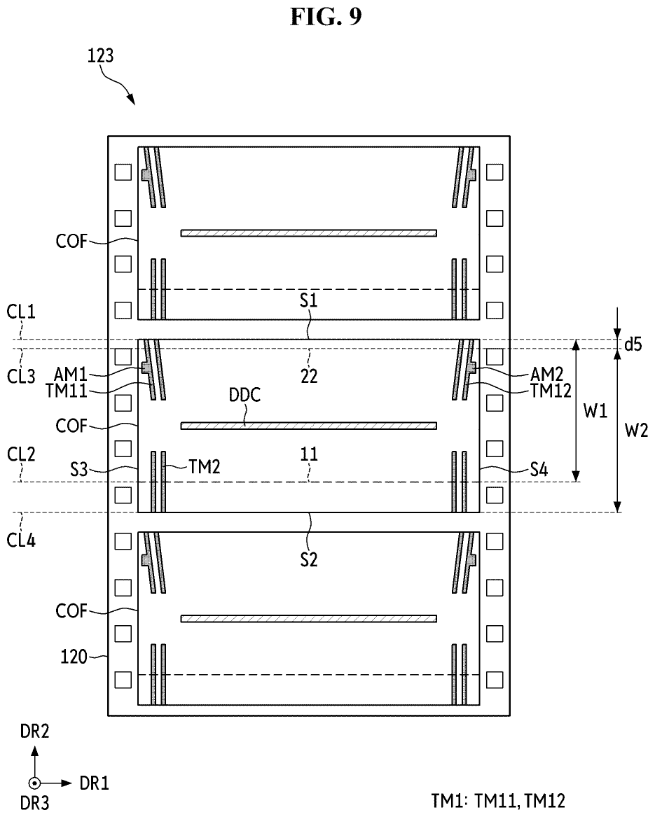

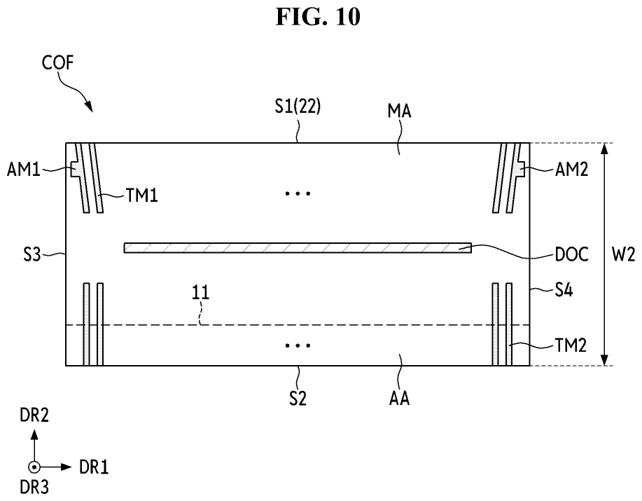

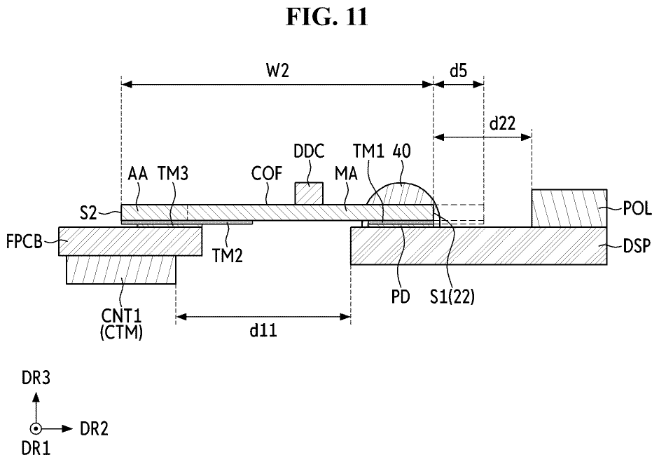

FIG. 9 is a plan view of a base film 123 according to some embodiments. FIG. 10 is a plan view of a first circuit board COF separated from the base film 123 of FIG. 9. FIG. 11 is a cross-sectional view of a display device according to some embodiments in which the first circuit board COF of FIG. 10 is attached.

First, as illustrated in FIG. 9, the base film 123 including a plurality of first circuit boards COF and a film 120 connecting the first circuit boards COF to each other may be prepared.

Next, a first circuit board COF of the base film 123 may be photographed by a photographing unit. For example, a first circuit board COF of the base film 123 which is to be connected to a display panel DSP may be photographed. In other words, first terminals TM1 and alignment marks AM1 and AM2 of the first circuit board COF may be photographed. Accordingly, a first outermost terminal TM11, a second outermost terminal TM12, a first board alignment mark AM1 and a second board alignment mark AM2 of the first circuit board COF of the base film 123 may be photographed. Next, through image analysis of the photographed first circuit board COF, a first distance d1 between the first outermost terminal TM11 and the second outermost terminal TM12 located between the first board alignment mark AM1 and the second board alignment mark AM2 may be calculated (operation S101). In FIG. 9, the base film 123 including three first circuit boards COF is illustrated. Among the three first circuit boards COF, a first circuit board COF to be connected to the display panel DSP may be a first circuit board COF located in the middle. First circuit boards COF located on both sides of the first circuit board COF in the middle may be, for example, first circuit boards COF to be connected to different display panels (e.g., display panels having different specifications).

Next, pads PD and alignment marks AM11 and AM22 of the display panel DSP may be photographed by the photographing unit. Accordingly, a first outermost pad PD11, a second outermost pad PD12, a first panel alignment mark AM11, and a second panel alignment mark AM22 of the display panel DSP may be photographed. Next, through image analysis of the photographed display panel DSP, a second distance d2 between the first outermost pad PD11 and the second outermost pad PD12 located between the first panel alignment mark AM11 and the second panel alignment mark AM22 may be calculated (operation S102).

Next, based on the first distance d1 and the second distance d2 described above, a correction movement distance of the first circuit board COF (e.g., a correction movement distance in the second direction DR2) for alignment between the first terminals TM1 of the first circuit board COF included in the base film 123 and the pads PD of the display panel DSP may be calculated. For example, the correction movement distance of the first circuit board COF may be calculated by the following equation (operation S103).

$$Y = ( Pp - Cp ) * tan θ$$

In the above equation, Y may be the correction movement distance of the first circuit board COF, Pp may be the second distance d2 described above, Cp may be the first distance d1 described above, and a terminal angle θ may be an angle of the first outermost terminal TM11 (or the first outermost pad PD11). For example, as illustrated in FIG. 4, the terminal angle θ may be an angle between the first outermost terminal TM11 and a virtual extension line parallel to a first side S1 of the first circuit board COF.

The correction movement distance Y of the first circuit board COF may mean, for example, a movement distance of the first circuit board COF in the second direction DR2 in a state where the first board alignment mark AM1 of the first circuit board COF and the first panel alignment mark AM11 of the display panel DSP are aligned with each other and where the second board alignment mark AM2 of the first circuit board COF and the second panel alignment mark AM22 of the display panel DSP are aligned with each other.

When the correction movement distance Y of the first circuit board COF included in the base film 123 is calculated by the above equation, a cutting position of the base film 123 may be determined based on the correction movement distance Y (operation S104).

For example, as illustrated in FIG. 9, cutting positions of the base film 123 before the correction movement distance Y is applied may correspond to the first side S1 of the first circuit board COF and a boundary line 11 between a main area MA and an auxiliary area AA of the first circuit board COF, respectively. In this case, the base film 123 may be cut along a first cutting line CL1 overlapping the first side S1 of the first circuit board COF and parallel to the first side S1 and a second cutting line CL2 overlapping the boundary line 11 of the first circuit board COF and parallel to the boundary line 11. In this case, a first circuit board COF having a first width W1 may be fabricated from the base film 123. The first circuit board COF having the first width W1 may include the main area MA. For example, the first circuit board COF of the first width W1 may include the first side S1 corresponding to the first cutting line CL1 and a second side S2 corresponding to the second cutting line CL2.

On the other hand, the cutting positions of the base film 123 when the correction movement distance Y is applied may correspond to a correction line 22 between the first side S1 of the first circuit board COF and a data driver circuit DDC, and the second side S2 of the first circuit board COF, respectively. In this case, the base film 123 may be cut along a third cutting line CL3 overlapping the correction line 22 of the first circuit board COF and parallel to the correction line 22 and a fourth cutting line CL4 overlapping the second side S2 of the first circuit board COF and parallel to the second side S2. Here, the correction line 22 of the first circuit board COF may mean, for example, a virtual line moved from the first side S1 of the first circuit board COF toward the second side S2 (or the data driver circuit DDC) by the correction movement distance Y described above. In other words, a distance d5 between the first cutting line CL1 and the third cutting line CL3 may be equal (or substantially equal) to the correction movement distance Y described above.

As the base film 123 is cut along the third cutting line CL3 and the fourth cutting line CL4 detected based on the correction movement distance Y as described above, a first circuit board COF illustrated in FIG. 10 may be fabricated from the base film 123. For example, a first circuit board COF having a second width W2 may be fabricated. In this case, the first circuit board COF of the second width W2 may include the main area MA and the auxiliary area AA. For example, the first circuit board COF of the second width W2 may include the first side S1 corresponding to the third cutting line CL3 and the second side S2 corresponding to the fourth cutting line CL4. Here, the second width W2 may be different from the first width W1. For example, the second width W2 may be greater than the first width W1.

Next, the first circuit board COF of FIG. 10 may be placed on the display panel DSP (operation S106).

Next, a preliminary alignment operation may be performed between the first circuit board COF and the display panel DSP based on the above-described correction movement distance Y. For example, in a state where the first board alignment mark AM1 of the first circuit board COF and the first panel alignment mark AM11 of the display panel DSP are aligned with each other and where the second board alignment mark AM2 of the first circuit board COF and the second panel alignment mark AM22 of the display panel DSP are aligned, the first circuit board COF may be moved along the second direction DR2 by the correction movement distance Y (e.g., d5). Accordingly, the first terminals TM1 of the first circuit board COF and the pads PD of the display panel DSP may be aligned to overlap each other, respectively.

Next, as illustrated in FIG. 11, the first circuit board COF and the display panel DSP may be physically and electrically connected to each other. For example, the first terminals TM1 of the first circuit board COF and the pads PD of the display panel DSP may be connected to each other through a connecting member such as an anisotropic conductive film.

Then, as illustrated in FIG. 11, a distance d22 between the first side S1 of the first circuit board COF and a polarizer POL may satisfy a tolerance. For example, because the width of the first circuit board COF is reduced by the correction movement distance of the first circuit board COF (e.g., the distance d5 between the first cutting line CL1 and the third cutting line CL3), the distance d22 between the first side S1 of the first circuit board COF and the polarizer POL can satisfy the tolerance.

Next, a second circuit board FPCB may be connected to the first circuit board COF. For example, third terminals TM3 of the second circuit board FPCB may be connected to second terminals TM2 of the first circuit board COF. For example, the third terminals TM3 of the second circuit board FPCB and the second terminals TM2 of the first circuit board COF may be connected to each other through a connecting member such as an anisotropic conductive film. At this time, the third terminals TM3 of the second circuit board FPCB may be respectively connected to the second terminals TM2 of the first circuit board COF while overlapping at least a part of the auxiliary area AA of the first circuit board COF so that a distance d11 between a connector module CTM and the display panel DSP satisfies a tolerance.

Therefore, according to the method of fabricating the display device 100 of according to some embodiments, the first terminals TM1 of the first circuit board COF and the pads PD of the display panel DSP can be correctly aligned with each other, while each of the distance d11 between the connector module CTM and the display panel DSP and the distance d22 between the first circuit board COF and the polarizer POL can satisfy a tolerance.

According to a display device, an electronic device including the same, and a method of fabricating the same, it may be possible to satisfy a tolerance while preventing or reducing misalignment between a circuit board and a display panel.

The display device according to the embodiment can be applied to various electronic devices. The electronic device according to one embodiment includes the display device described above and may further include modules or devices having additional functions in addition to the display device.

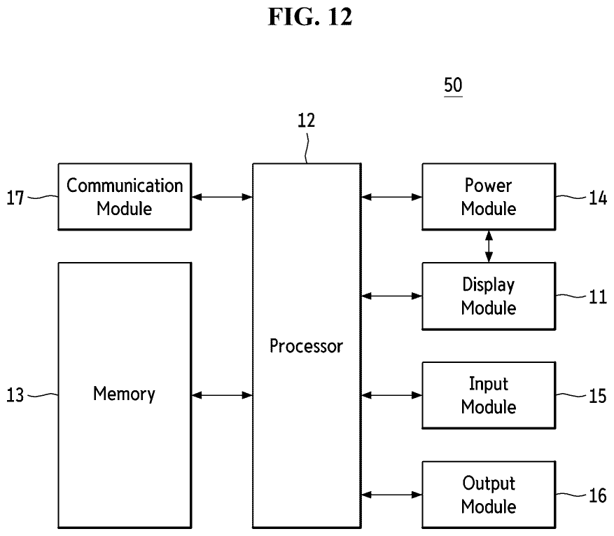

FIG. 12 is a block diagram of an electronic device according to one embodiment. Referring to FIG. 12, the electronic device 50 according to one embodiment may include a display module, a processor 12, a memory 13, and a power module 14. The electronic device 5000 may further include an input module 14, a non-image output module 15 and/or a communication module 16.

The electronic device 50 may output various information in the form of images through the display module 11. When the processor 12 executes an application stored in the memory 13, image information provided by the application may be provided to the user through the display module 1100. The power module 14 may include a power supply module such as a power adapter or a battery device, and a power conversion module that converts the power supplied by the power supply module to generate power required for the operation of the electronic device 5000. The input module 14 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 5000 and an external device, and may include a receiving unit and a transmitting unit. At least one of the components of the electronic device 50 described above

may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 11 other than the display device.

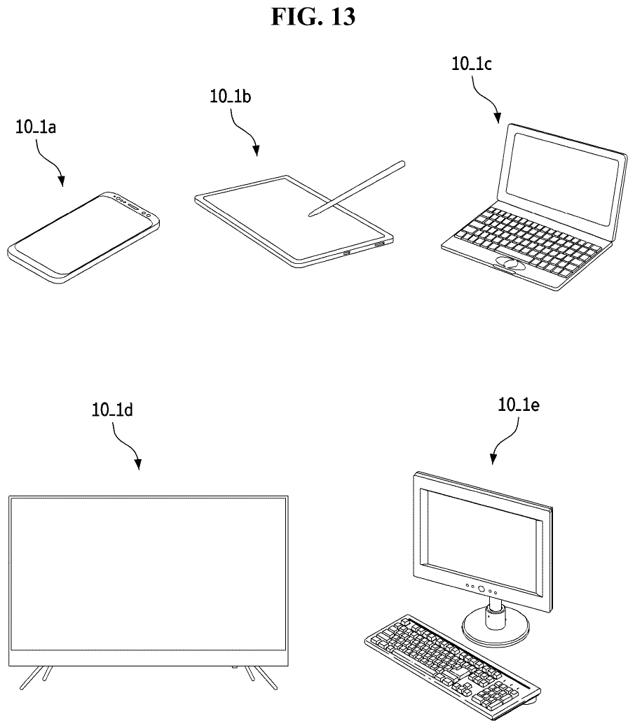

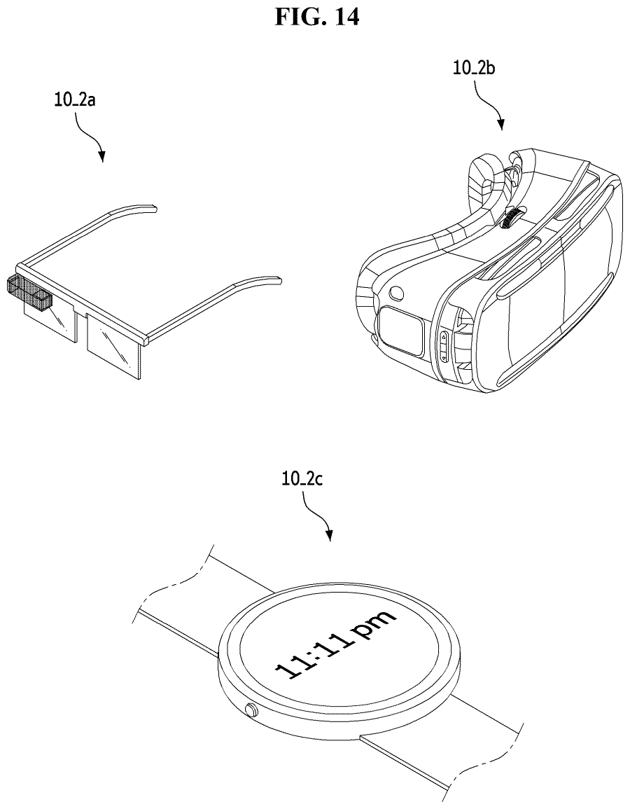

FIGS. 13, 14, and 15 are schematic diagrams of electronic devices according to various embodiments. FIGS. 13 to 15 illustrate examples of various electronic devices to which the display device according to the embodiments is applied.

FIG. 13 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

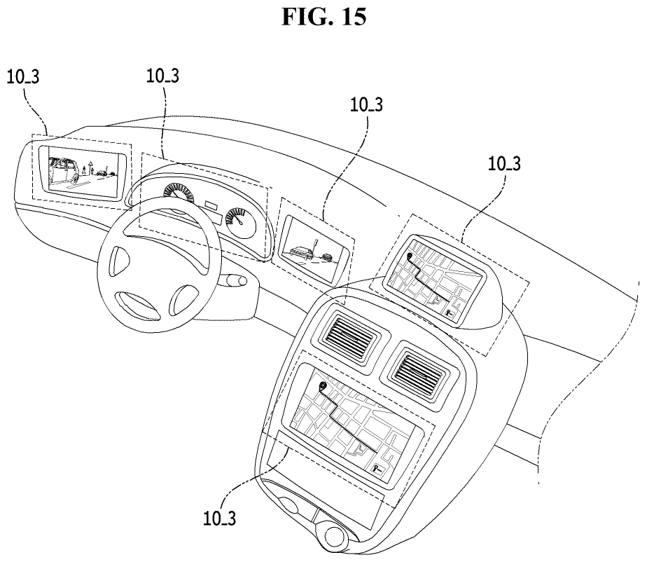

FIG. 14 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

The smart watch 10_2c includes a biometric sensor as an input device, and may provide biometric information recognized by the biometric sensor to the user through the display module. FIG. 15 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

However, the characteristics of embodiments according to the present disclosure are not restricted to the characteristic specifically described forth herein. The above and other characteristics of embodiments according to the present disclosure will become more apparent to one of ordinary skill in the art to which embodiments according to the present disclosure pertains by referencing the claims, and their equivalents.

It will be able to be understood by one of ordinary skill in the art to which the present disclosure belongs that the present disclosure may be implemented in other specific forms without changing the technical spirit or essential features of the present disclosure. Therefore, it is to be understood that the disclosed embodiments described above are illustrative rather than being restrictive in all aspects. It is to be understood that the scope of embodiments according to the present disclosure are defined by the claims, and their equivalents, rather than the detailed description described above and all modifications and alterations derived from the claims and their equivalents fall within the scope of the present disclosure.

What is claimed is:

1. A display device comprising:
a display panel;
a first circuit board comprising a first terminal connected to a pad of the display panel;
a second circuit board comprising a third terminal connected to a second terminal of the first circuit board; and
a driver circuit on the first circuit board,
wherein a first terminal area of the first circuit board on which the first terminal is located and a second terminal area of the first circuit board on which the second terminal is located have different sizes.

2. The display device of claim 1, wherein the second terminal area is larger than the first terminal area.

3. The display device of claim 1, wherein the first circuit board comprises:
a main area comprising the first terminal area, the driver circuit, and a first part of the second terminal area; and
an auxiliary area comprising a second part of the second terminal area.

4. The display device of claim 3, wherein the second terminal area comprises the auxiliary area.

5. The display device of claim 3, wherein the third terminal of the second circuit board overlaps the main area.

6. The display device of claim 3, wherein the third terminal of the second circuit board overlaps the main area and the auxiliary area.

7. The display device of claim 6, wherein the third terminal of the second circuit board overlaps the auxiliary area more than the main area.

8. The display device of claim 1, wherein the first circuit board comprises:
a first side overlapping the display panel;
a second side overlapping the second circuit board;
a third side connected to one side of the first side and one side of the second side and overlapping the display panel and the second circuit board; and
a fourth side connected to another side of the first side and another side of the second side and overlapping the display panel and the second circuit board.

9. The display device of claim 8, wherein the first terminal comprises a plurality of first terminals comprising a center terminal, and at least one of the first terminals has a diagonal shape.

10. The display device of claim 9, wherein first terminals between the center terminal and the third side of the first circuit board are more rotated along a counterclockwise direction as a distance from the center terminal increases, and first terminals between the center terminal and the fourth side of the first circuit board are more rotated along a clockwise direction as the distance from the center terminal increases.

11. The display device of claim 10, wherein the first circuit board further comprises:
a first board alignment mark on an outer surface of a first outermost terminal closest to the third side among the first terminals; and
a second board alignment mark on an outer surface of a second outermost terminal closest to the fourth side among the first terminals.

12. The display device of claim 11, wherein the pad comprises a plurality of pads comprising a center pad, and at least one of the pads has a diagonal shape.

13. The display device of claim 12, wherein pads between the center pad and a first side of the display panel are more rotated along the counterclockwise direction as a distance from the center pad increases, and pads between the center pad and a second side of the display panel are more rotated along the clockwise direction as the distance from the center pad increases.

14. The display device of claim 13, wherein the display panel further comprises:
a first panel alignment mark on an outer surface of a first outermost pad closest to the first side of the display panel among the pads; and
a second panel alignment mark on an outer surface of a second outermost pad closest to the second side of the display panel among the pads.

15. The display device of claim 14, wherein a first distance between the first outermost terminal and the second outermost terminal located between the first board alignment mark and the second board alignment mark is greater than a second distance between the first outermost pad and the second outermost pad located between the first panel alignment mark and the second panel alignment mark.

16. An electronic device comprising the display device of claim 1, wherein the electronic device is one of a mobile phones, a smartphone, a tablet personal computer (PC), a smart watch, a watch phone, a mobile communication terminal, an electronic notebook, an electronic book, a portable multimedia player (PMP), a navigation device, an ultra-mobile PC (UMPC), a television, a notebook computer, a monitor, a billboard, or an Internet of things (IoT) device.

17. A method of fabricating a display device, the method comprising:
preparing a base film which comprises a plurality of first circuit boards;
calculating a first distance between a first outermost terminal and a second outermost terminal of any one first circuit board of the base film;
calculating a second distance between a first outermost pad and a second outermost pad of a display panel;
calculating a correction movement distance of the any one first circuit board based on the first distance and the second distance;
determining a cutting position of the base film based on the correction movement distance of the any one first circuit board;
forming a first circuit board from among the plurality of first circuit boards by cutting the base film along the cutting position;
placing the first circuit board on the display panel; and
performing preliminary alignment between the first circuit board and the display panel based on the correction movement distance.

18. The method of claim 17, wherein the first distance is a distance between the first outermost terminal and the second outermost terminal located between a first board alignment mark and a second board alignment mark on the first circuit board, and the second distance is a distance between the first outermost pad and the second outermost pad located between a first panel alignment mark and a second panel alignment mark on the display panel.

19. The method of claim 18, wherein the first distance between the first outermost terminal and the second outermost terminal located between the first board alignment mark and the second board alignment mark is greater than the second distance between the first outermost pad and the second outermost pad located between the first panel alignment mark and the second panel alignment mark.

20. The method of claim 17, wherein at least one of first terminals of the first circuit board comprising the first outermost terminal or the second outermost terminal has a diagonal shape, and at least one of pads of the display panel comprising the first outermost pad or the second outermost pad has a diagonal shape.

21. The method of claim 17, further comprising connecting a second circuit board to the first circuit board.

22. An electronic device comprising:
a display panel including a screen;
wherein the display device comprises:
a first circuit board comprising a first terminal connected to a pad of the display panel;
a second circuit board comprising a third terminal connected to a second terminal of the first circuit board; and
a driver circuit on the first circuit board,
wherein a first terminal area of the first circuit board on which the first terminal is located and a second terminal area of the first circuit board on which the second terminal is located have different sizes.
